(19) United States
(12) Patent Application Publication
(10) Pub. No.: US 2026/0230075 A1
(43) Pub. Date: Aug. 6, 2026

(54) EDGE-TRIGGERED TRANSCEIVER IN SEMICONDUCTOR PACKAGE AND CALIBRATION METHOD THEREOF

(71) Applicant: TAIWAN SEMICONDUCTOR MANUFACTURING COMPANY LTD., HSINCHU (TW)

(72) Inventor: WEI SHUO LIN, HSINCHU (TW)

(21) Appl. No.: 19/046,480

(22) Filed: Feb. 5, 2025

(51) Int. Cl. H03K 19/00

(52) U.S. Cl. CPC H03K 19/0016

(57) ABSTRACT

A semiconductor package is provided. The semiconductor package includes an interposer, a first die and a second die over the interposer, and an edge-triggered transceiver. The edge-triggered transceiver includes a transfer lane disposed in the interposer, a capacitor, a transmitter, and a receiver. The receiver includes an inverter having an input terminal coupled to a second end of the transfer lane and an output terminal, a first resistor coupled to the input terminal of the first inverter, a second resistor coupled between the input terminal and the output terminal of the first inverter, a first switch coupled between the first resistor and a node of a first reference voltage, and a second switch coupled between the first resistor and a node of a second reference voltage. The inverter receives the second signal and provides a third signal to turn on one of the first and second switches.

### BACKGROUND

When communicating between circuits, whether on the same die (or chip) or across different dies (or chips), the process can be limited by the characteristics of the “channel,” which refers to the electrical connections between the communication circuits. For example, transmitting signals in short reach link via an interposer can be impeded by the bandwidth constraints of the metal lines in the interposer, largely influenced by RC (resistance-capacitance) factors. These constraints not only reduce the bandwidth of each pin due to wiring losses but also decrease the energy per bit. Therefore, in short reach link applications, it is important to strike a balance between power consumption and the complexity of transceiver design.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or decreased for clarity of discussion.

FIG. 1 is a circuit schematic of an edge-triggered transceiver (ETT), in accordance with some embodiments of the present disclosure.

FIG. 2 shows the signal waveform of the ETT transmitter in FIG. 1, in accordance with some embodiments of the present disclosure.

FIG. 3 illustrates a simulation model of the ETT, in accordance with some embodiments of the present disclosure.

FIGS. 4A and 4B illustrate the relationships between the unit interval (UI) of the signal S3 and sensitivities of the capacitor and the variable resistor, respectively, in accordance with some embodiments of the present disclosure.

FIGS. 4C and 4D illustrate the relationships between the UI of the signal S3 and sensitivities of the variable capacitor, in accordance with some embodiments of the present disclosure.

FIG. 5 illustrates a simulation model of the ETT, in accordance with some embodiments of the present disclosure.

FIGS. 6A and 6B illustrate the relationships between the UI of the signal V1 and the resistors R1 and R2, in accordance with some embodiments of the present disclosure.

FIGS. 7A and 7B illustrate the transient result and eye diagram of the signals in the ETT with the channel model, respectively, in accordance with some embodiments of the present disclosure.

FIGS. 8A through 8D are circuit schematic illustrating various semiconductor packages, in accordance with some embodiments of the present disclosure.

FIG. 9 is a circuit schematic of the ETT, in accordance with some embodiments of the present disclosure.

FIG. 10 illustrates a calibration method, in accordance with some embodiments of the present disclosure.

FIG. 11 illustrates various phases in the calibration method of FIG. 10, in accordance with some embodiments of the present disclosure.

FIGS. 12A through 12D are circuit schematic of various ETT receivers, in accordance with some embodiments of the present disclosure.

### DETAILED DESCRIPTION

The following disclosure provides many different embodiments, or examples, for implementing different features of the provided subject matter. Specific examples of components and arrangements are described to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

While embodiments of the present disclosure are discussed in detail, it should be appreciated that the present disclosure provides many applicable inventive concepts that can be embodied in a wide variety of specific contexts. The specific embodiments discussed are merely illustrative and do not limit the scope of the disclosure.

Further, spatially relative terms, such as “beneath”, “below”, “above”, “upper”, “lower”, “left”, “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

According to the embodiments, a low-power edge-triggered transceiver is provided for high-speed die-to-die transmission in a package. The edge-triggered transceiver includes a transmitter, a receiver and a transfer lane coupled between the transmitter and the receiver. The transfer lane is disposed in an interposer of the package. The transmitter is configured to provide an input signal to the transfer lane through a capacitor, so as to transmit the AC component of the input signal to the receiver. The receiver is configured to receive the signal from the transfer lane and provide a DC level for the received signal, so that each edge of the input signal is received correctly. The edge-triggered transceiver further includes a calibration circuit for calibrating the duty cycle of the input signal, so as to improve the eye opening of the signal in the receiver. Furthermore, the input signal is transmitted through the transfer lane without re-buffers, thereby decreasing power consumption.

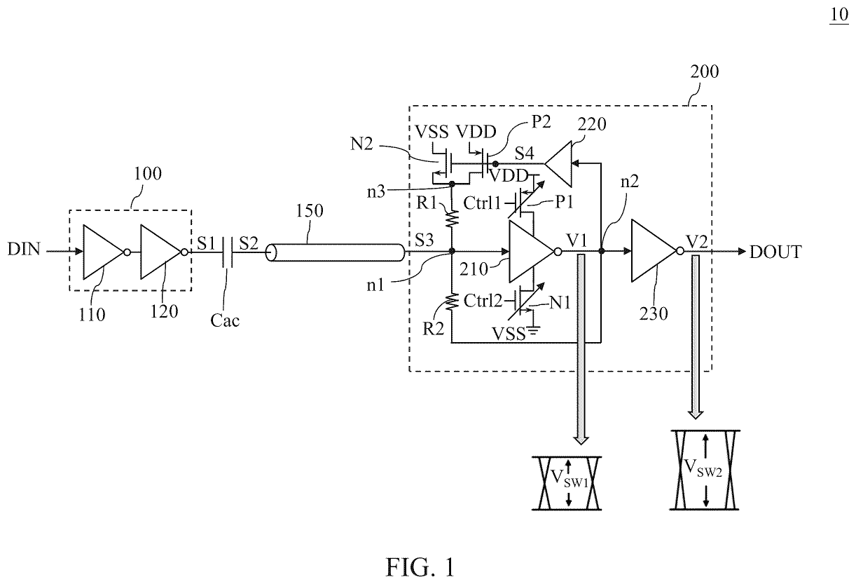

FIG. 1 is a circuit schematic of an edge-triggered transceiver (ETT) 10, in accordance with some embodiments of the present disclosure. The ETT 10 is implemented in a semiconductor package, and the ETT 10 includes an ETT transmitter 100, an ETT receiver 200, a transfer lane 150 and a capacitor Cac. The ETT transmitter 100 is coupled to the transfer lane 150 through the capacitor Cac. In some embodiments, the transfer lane 150 is a trace (or a transmission line, a conductive line) implemented in an interposer of the semiconductor package.

The ETT transmitter 100 includes the inverters 110 and 120 connected in series. The number of inverters is only an example and is not intended to limit the disclosure. The ETT transmitter 100 may include more or fewer inverters. In some embodiments, the inverters of the ETT transmitter 100 can be replaced by the buffers. The ETT transmitter 100 is configured to receive the input signal DIN and provide a signal S1 to the capacitor Cac. The capacitor Cac is configured to block the DC component of the signal S1 and couple the AC component of the signal S1 to the transfer lane 150 as a signal S2. The transfer lane 150 is configured to transmit the signal S2 to the ETT receiver 200 as a signal S3. The ETT receiver 200 is configured to receive the signal S3 and provide the output signal DOUT.

The ETT receiver 200 includes the inverters 210 and 230, the buffer 220, the resistors R1 and R2, the P-type transistors P1 and P2, and the N-type transistors N1 and N2. The inverters 210 and 230 are connected in series. The inverter 210 has an input terminal coupled to a first node n1 and an output terminal coupled to a second node n2. The inverter 210 is configured to receive the signal S3 from transfer lane 150 and generate the signal V1 at the second node n2. The inverter 230 is configured to receive the signal V1 and generate the signal V2 as the output signal DOUT. The voltage swing V_{SW1} of the signal V1 is less than the voltage swing V_{SW2} of the signal V2. The transfer lane 150 has a first end coupled to the capacitor Cac and a second end coupled to the node n1.

The resistor R1 is coupled between the first node n1 and the third node n3, and the resistor R2 is coupled between the first node n1 and the second node n2. The P-type transistor P2 is coupled between the third node n3 and a node of a power supply voltage VDD (e.g., a first reference voltage), and the N-type transistor N2 is coupled between the third node n3 and a node of a power supply voltage VSS (e.g., a second reference voltage). In the embodiment, the P-type transistor P2 and the N-type transistor N2 function as the switches. The buffer 220 is coupled between the node n2 and the gates of the P-type transistor P2 and the N-type transistor N2. The buffer 220 is configured to receive the signal V1 to provide the signal S4 with full swing to the P-type transistor P2 and the N-type transistor N2, so as to turn on the P-type transistor P2 or the N-type transistor N2. In other words, the signal V1 with the voltage swing V_{SW1} is amplified into the signal S4 with the voltage swing from the power supply voltage VDD to the power supply voltage VSS. In some embodiments, the buffer 220 is removed when the voltage swing V_{SW1} is sufficient to turn on the P-type transistor P2 and the N-type transistor N2.

In some embodiments, the P-type transistor P1 and the N-type transistor N1 are additional transistors for the inverter 210. For example, the inverter 210 includes a P-type transistor and an N-type transistor (not shown), and the gates of the P-type transistor and the N-type transistor are coupled to the node n1. The P-type transistor is coupled to a node of the power supply voltage VDD through the P-type transistor P1, and N-type transistor is coupled to a node of the power supply voltage VSS through the N-type transistor N1. The P-type transistor P1 is controlled by the control signal Ctrl1, and the N-type transistor N1 is controlled by the control signal Ctrl 2. In some embodiments, the control signals Ctrl1 and Ctrl2 are digital signals, and the sizes of the P-type transistor P1 and the N-type transistor N1 are controlled by the control signals Ctrl1 and Ctrl2, respectively. In some embodiments, the control signals Ctrl1 and Ctrl2 are analog signals, and the P-type transistor P1 and the N-type transistor N1 are biased by the control signals Ctrl1 and Ctrl2, respectively. In some embodiments, the P-type transistor P1 and the N-type transistor N1 are omitted in the ETT transmitter 100, and the sizes of the P-type transistor and the N-type transistor of the inverter 210 are controlled by the control signals Ctrl1 and Ctrl2, respectively.

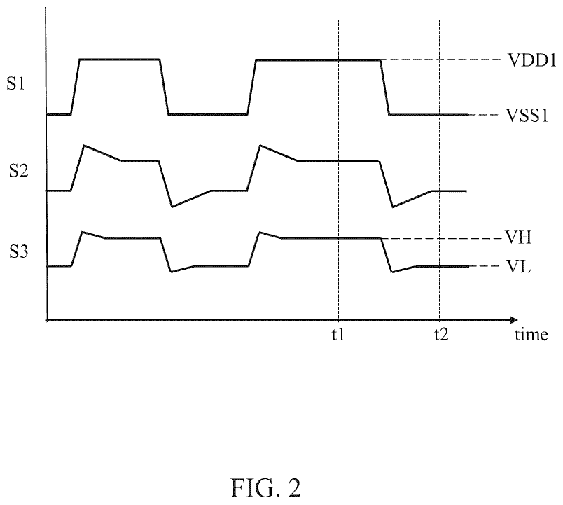

FIG. 2 shows the signal waveform of the ETT transmitter 100 in FIG. 1, in accordance with some embodiments of the present disclosure. The signal S1 includes a series of data consisting of the high logic level (e.g., “1”) corresponding to a power supply voltage VDD1 and the low logic level (e.g., “0”) corresponding to a power supply voltage VSS1. In some embodiments, the power supply voltages VDD1 and VSS1 of the ETT transmitter 100 are the same as the power supply voltages VDD and VSS of the ETT receiver 200. In some embodiments, the power supply voltage VDD1 and VSS1 of the ETT transmitter 100 is different from the power supply voltage VDD and VSS of the ETT receiver 200.

As described above, the DC component of the signal S1 is blocked by the capacitor Cac, so the signals S2 and S3 do not include the DC component of the signal S1. In such embodiment, the DC component of the signal S3 is provided by the resistors R1 and R2, the P-type transistor P2 and the N-type transistor N2. Thus, for the signal S1 having the power supply voltage VDD1 (i.e., the high logic level), the ETT receiver 200 is capable of providing the high voltage level VH as the signal S3, as shown at time t1. Similarly, for the signal S1 having the power supply voltage VSS1 (i.e., the low logic level “0”), the ETT receiver 200 is capable of providing the low voltage level VL as the signal S3, as shown at time t2.

At time t1, the ETT transmitter 100 is configured to provide the signal S1 with the power supply voltage VDD1 to the ETT receiver 200. In response to the AC component of the signal S1 at time t1, the N-type transistor N2 is turned off and the P-type transistor P2 is turned on by the buffer 220 according to the signal V1, and then the signal S3 with the high voltage level VH is generated through the voltage dividing circuit composed of the P-type transistor P2 and the resistors R1 and R2, as shown in the following formula:

$$VH = \frac{VDD \times R 2 + V 1 ( R 1 + Rp )}{R 1 + R 2 + Rp} ,$$

where Rp represents the equivalent resistance of the turned-on P-type transistor P2. When the resistance values of the resistors R1 and R2 are much larger than the resistance Rp, the high voltage level VH can be expressed as the following formula:

$$VH = \frac{VDD \times R 2 + V 1 \times R 1}{R 1 + R 2} ,$$

At time t2, the ETT transmitter 100 is configured to provide the signal S1 with the power supply voltage VSS1 to the ETT receiver 200. In response to the AC component of the signal S1 at time t2, the N-type transistor N2 is turned on and the P-type transistor P2 is turned off by the buffer 220 according to the signal V1, and then the signal S3 with the low voltage level VL is generated through the voltage dividing circuit composed of the N-type transistor N2 and the resistors R1 and R2, as shown in the following formula:

$$VL = \frac{VSS \times R 2 + V 1 ( R 1 + Rn )}{R 1 + R 2 + Rn} ,$$

where Rn represents the equivalent resistance of the turned-on N-type transistor N2. When the resistance values of the resistors R1 and R2 are much larger than the resistance Rn, the low voltage level VL can be expressed as the following formula:

$$VL = \frac{VSS \times R 2 + V 1 \times R 1}{R 1 + R 2} ,$$

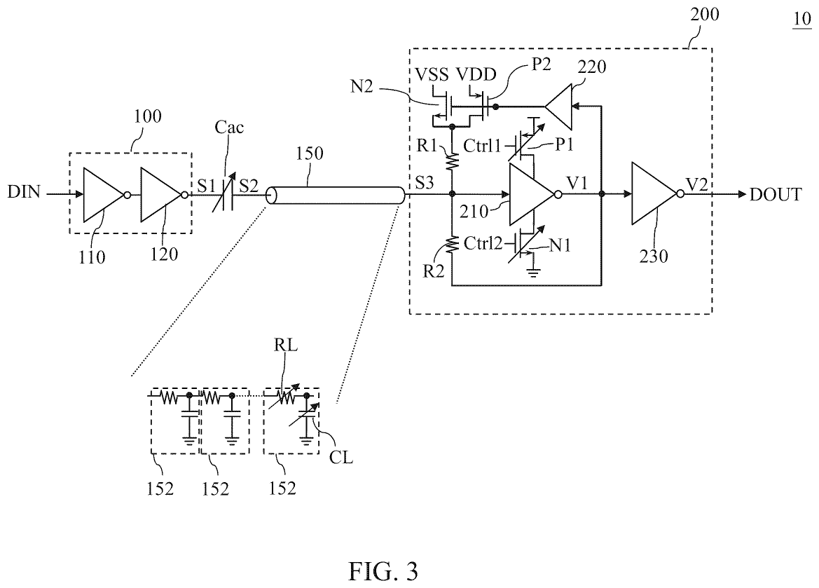

FIG. 3 illustrates a simulation model of the ETT 10, in accordance with some embodiments of the present disclosure. In the embodiment, the transfer lane 150 is modeled as a channel model including multiple-stage RC model 152, and the capacitor Cac is variable. Each RC model 152 includes a resistor RL corresponding to a channel parasitic resistor and a capacitor CL corresponding to a channel parasitic capacitor. In the embodiment, the resistor RL and the capacitor CL are variable. Furthermore, the number of the RC models 152 is determined by the length of the transfer lane 150. For example, when the transfer lane 150 is about 1600 μm, the channel model includes 10 stages RC models 152 connected in series. In the simulation model of FIG. 3, the capacitance value of the capacitor Cac is determined by analyzing the unit interval (UI) of the signal S3 with the variable resistor RL and a variable capacitor CL.

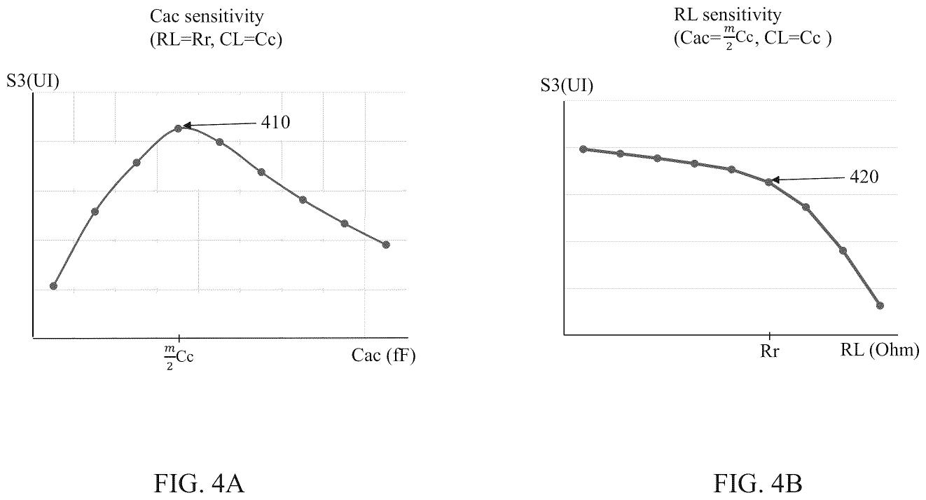

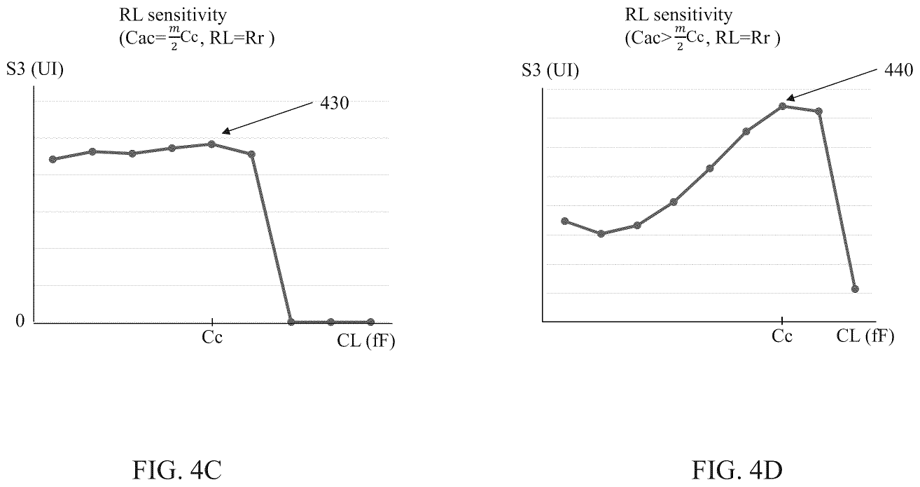

FIGS. 4A and 4B illustrate the relationships between the UI of the signal S3 and sensitivities of the capacitor Cac and the variable resistor RL, respectively, in accordance with some embodiments of the present disclosure. FIGS. 4C and 4D illustrate the relationships between the UI of the signal S3 and sensitivities of the variable capacitor CL, in accordance with some embodiments of the present disclosure. In the embodiment of FIGS. 4A through 4D, a high speed signal (e.g., 32 Gbps) is input as the input signal DIN, and the UI of the signal S3 is obtained during a simulation with the channel model of FIG. 3. During the simulation, the capacitance value of each variable capacitor CL is Cc, and the capacitance value of total variable capacitors CL in the transfer lane 150 is m*Cc, where m represents the number of the RC models 152 in the transfer lane 150. Furthermore, the resistance value of each variable resistor RL is Rr, and the resistance value of total variable resistors RL in the transfer lane 150 is m*Rr. In some embodiments, the resistance value Rr is as small as possible.

As shown in label 410 of FIG. 4A, the signal S3 has a maximum UI when the capacitor Cac has the capacitance value

$$\frac{m}{2} Cc ,$$

which is equal to half of total variable capacitors CL. As shown in label 420 of FIG. 4B, when the resistance value of the variable resistor RL is greater than Rr, the UI of the signal S3 will drop significantly. As shown in label 430 of FIG. 4C, the signal S3 has a maximum UI when the capacitor CL has the capacitance value Cc and the capacitor Cac has the capacitance value

$$\frac{m}{2} Cc .$$

As shown in label 440 of FIG. 4D, the signal S3 has a maximum UI when the capacitor CL has the capacitance value Cc and the capacitor Cac is greater than the capacitance value

$$\frac{m}{2} Cc .$$

Therefore, the capacitance value of capacitor Cac may be equal to or greater than half of total variable capacitors CL in the ETT 10. In some embodiments, the capacitance value of capacitor Cac is increased for larger channel parasitic capacitor (e.g., the capacitor CL in RC model 152), the drive capability of the ETT transmitter 100 needs to be increased as well.

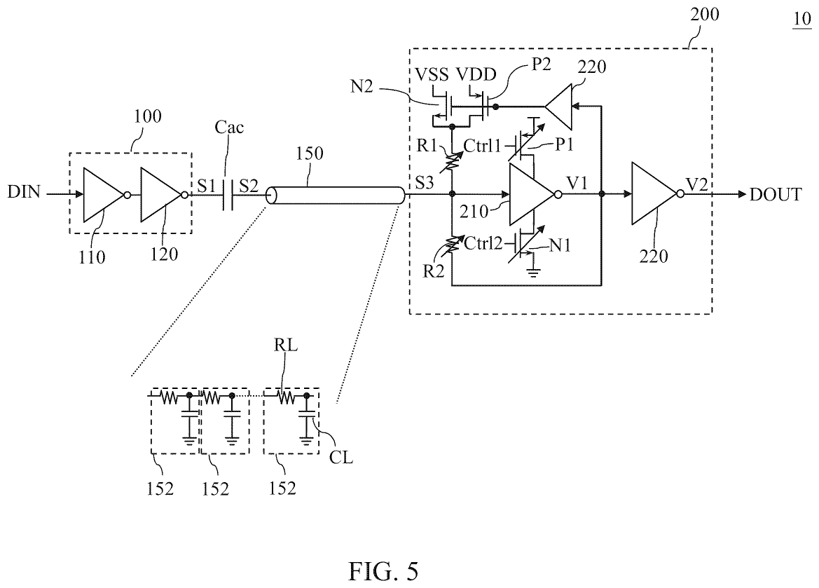

FIG. 5 illustrates a simulation model of the ETT 10, in accordance with some embodiments of the present disclosure. In the embodiment, the transfer lane 150 is modeled as a channel model including multiple-stage RC model 152, and the resistors R1 and R2 are variable. Each RC model 152 includes the resistor RL and the capacitor CL, and the resistance value of the resistor RL and the capacitance values of capacitors CL and Cac are determined according to the simulation model of the ETT 10 in FIG. 3. By using the simulation model of FIG. 5, the resistance values of resistors R1 and R2 are determined by analyzing the unit interval (UI) of the signal V1. In some embodiments, when the resistance value of resistor R1 increases and exceeds a specific value, e.g., 9K Ohm, the signal V1 disappears.

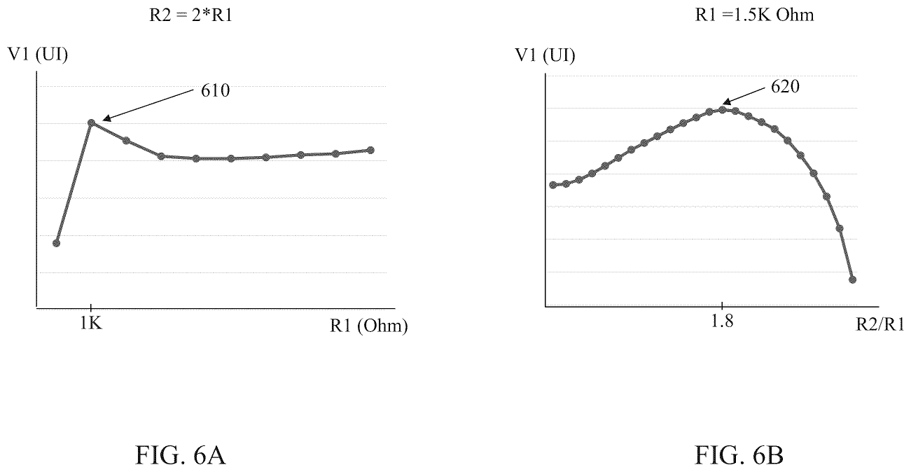

FIGS. 6A and 6B illustrate the relationships between the UI of the signal V1 and the resistors R1 and R2, in accordance with some embodiments of the present disclosure. In the embodiment of FIGS. 6A and 6B, a high speed signal (e.g., 32 Gbps) is input as the input signal DIN, and the UI of the signal V1 is obtained during a simulation with the channel model of FIG. 5. During the simulation, the capacitance value Cc of each variable capacitor CL is fixed, and the resistance value Rr of each variable resistor RL is fixed. Furthermore, the capacitor Cac has the capacitance value

$$\frac{m}{2} Cc ,$$

where m represents the number of the RC models 152 in the transfer lane 150.

As shown in label 610 of FIG. 6A, the signal V1 has a maximum UI when the resistance value of resistor R1 is equal to 1K Ohm and the resistor R2 is twice the resistor R1. As shown in label 620 of FIG. 6B, the signal V1 has a maximum UI when the resistance value of resistor R1 is equal to 1.5K Ohm and the resistor R2 is 1.8 times the resistor R1. Therefore, the resistance value of resistor R1 is in a range about from 1K Ohm to 2K Ohm in the ETT 10. Furthermore, the resistor R2 is twice the resistor R1 in the ETT 10 for layout matching.

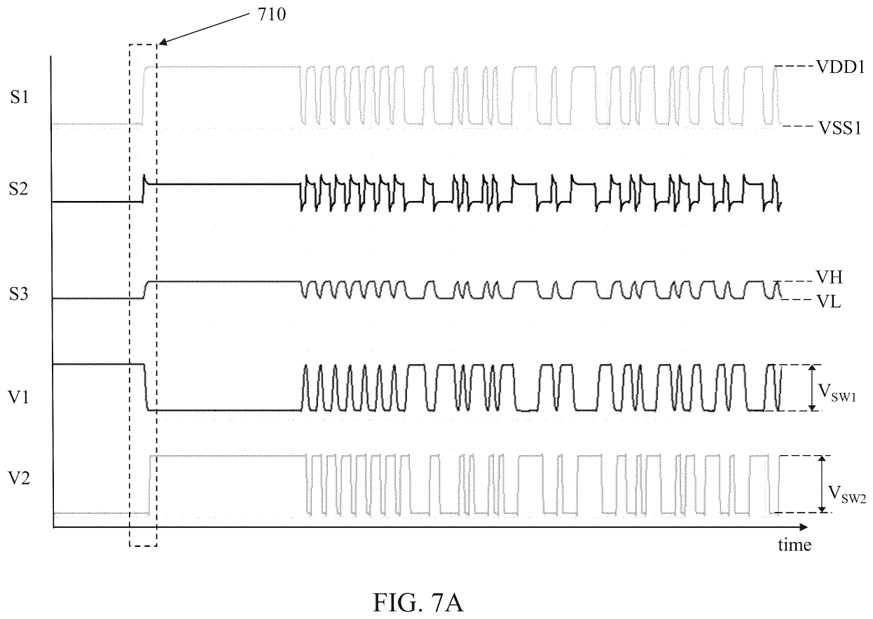

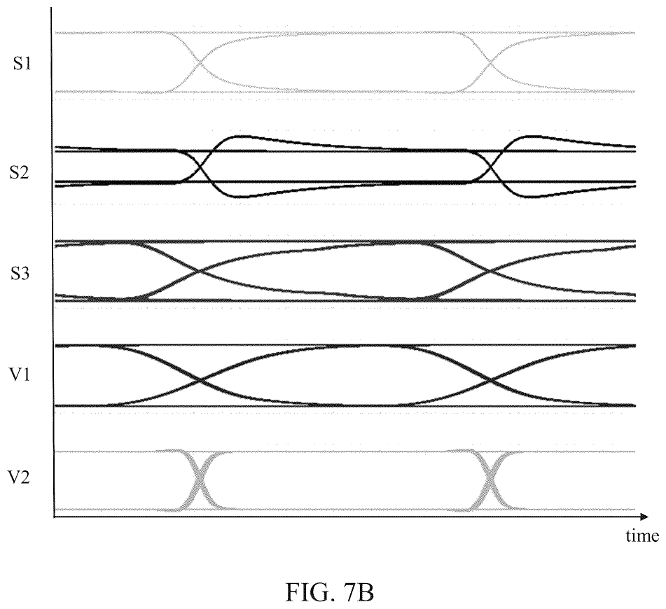

FIGS. 7A and 7B illustrate the transient result and eye diagram of the signals in the ETT 10 with the channel model, respectively, in accordance with some embodiments of the present disclosure. In the embodiment of FIGS. 7A and 7B, a high speed signal (e.g., 32 Gbps) is input as the input signal DIN. As described above, the DC component of the signal S3 is provided by the resistors R1 and R2, the P-type transistor P2 and the N-type transistor N2, thereby avoiding baseline wander for the data with non-return to zero (NRZ) encoding, especially on the first edge. As shown in label 710 of FIG. 7A, the first edge of signal S1 is correctly passed to the signal V2 through the transfer lane 150 and the ETT receiver 200. Furthermore, the eye diagram of the signals in the ETT 10 includes the first edge range labeled by 710. By appropriately selecting the values of resistors and capacitors in the ETT 10, the eye opening of signal V2 is greater than the eye opening of signal S1. In some embodiments, the resistor RL in the RC model 152 as small as possible is good for eye quality.

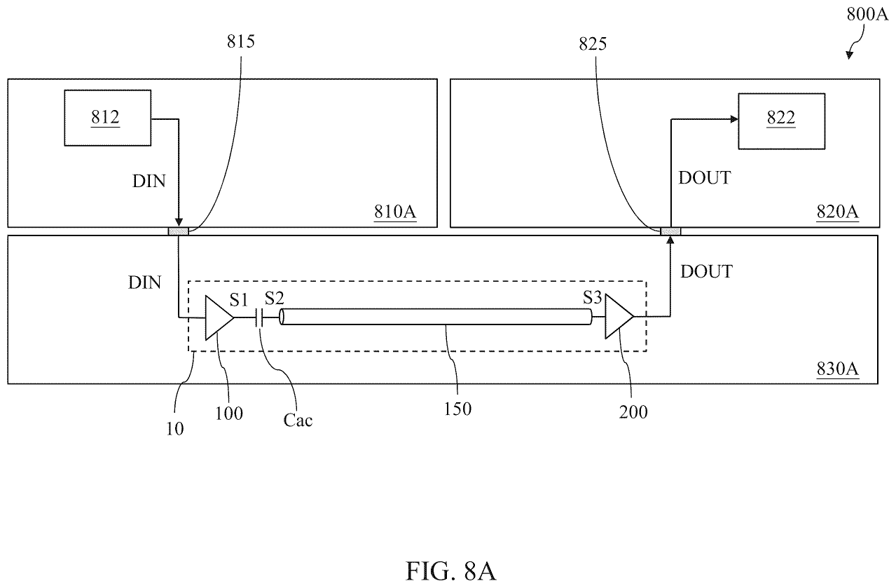

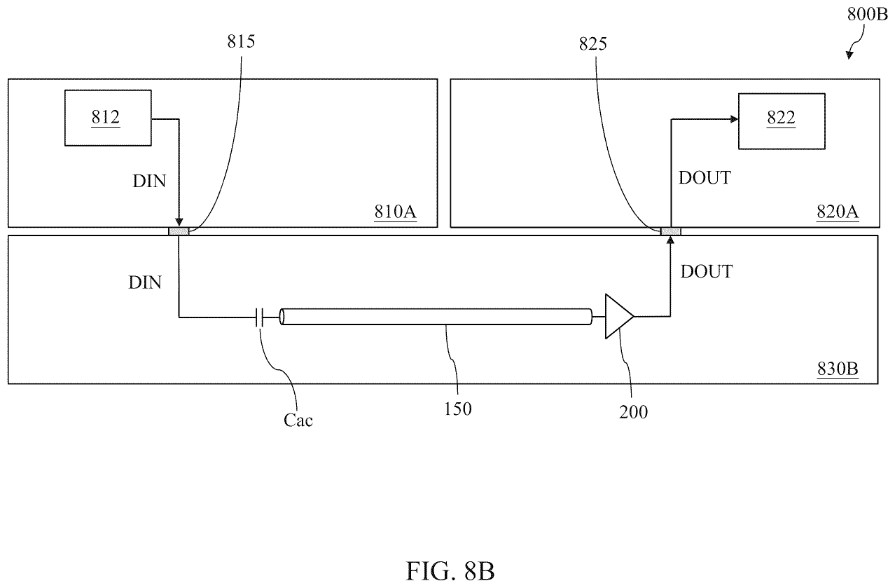

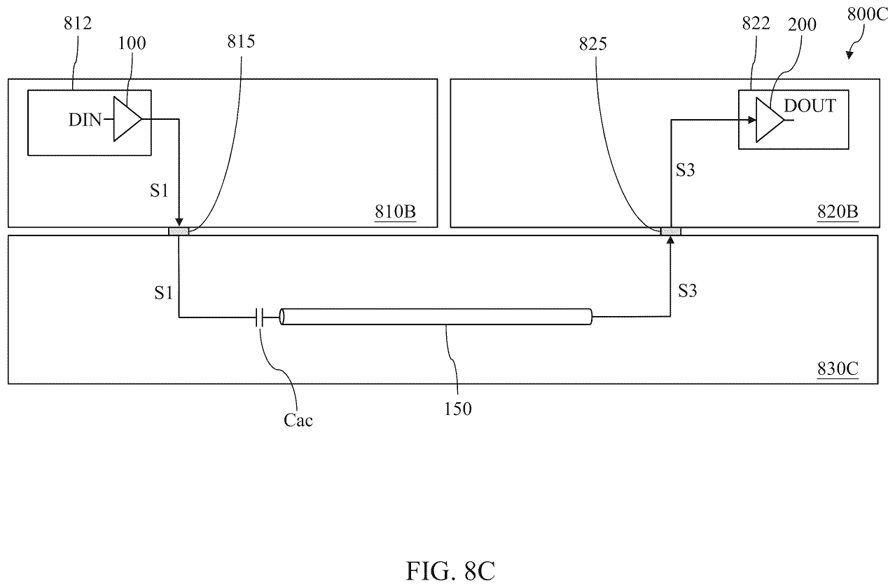

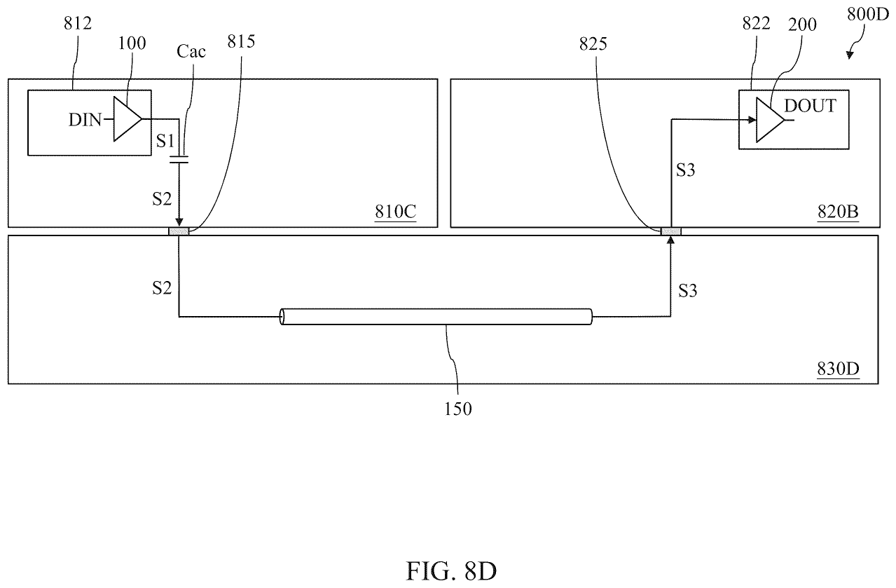

FIG. 8A is a circuit schematic illustrating a semiconductor package 800A, in accordance with some embodiments of the present disclosure. The semiconductor package 800A includes a first die 810A, a second die 820A and an interposer 830A. In the embodiment of FIG. 8A, the first die 810A and the second die 820A are disposed on the interposer 830A. Each of the first die 810A and the second die 820A can be or include a processor, an application specific integrated circuit (ASIC), a programmable integrated circuit (e.g., field-programmable gate array (FPGA) or complex programmable logic device (CPLD)), memory die, or the like.

The first die 810A includes a transmitter (or an input/output circuit) 812, and the transmitter 812 is configured to provide the input signal DIN to the interposer 830A through a conductive terminal 815. The interposer 830A includes the ETT 10, and the ETT 10 is configured to receive the input signal DIN from the first die 810A and provide the output signal DOUT to the second die 820A through a conductive terminal 825. The second die 820A includes a receiver (or an input/output circuit) 822, and the receiver 822 is configured to receive the output signal DOUT from the conductive terminal 825. To simplify the explanation, the interconnection between the transmitter 812 and the conductive terminal 815 in the first die 810A and the interconnection between the receiver 822 and the conductive terminal 825 in the second die 820A are omitted. In FIG. 8A, one signal path transferred from the first die 810A to the second die 820A is shown as an example. In the semiconductor package 800A, more signals are transmitted from first die 810A to second die 820A through the respective ETTs 10.

The conductive terminals 815 and 825 are formed on the front surface of the interposer 830A to electrically connect to the first die 810A and the second die 820A. In some embodiments, the conductive terminals 815 and 825 may be formed of conductive material(s) including copper, aluminum, gold, nickel, silver, palladium, tin, solder, metal alloy, the like, or combinations thereof. In some embodiments, each of the conductive terminals 815 and 825 includes a conductive bump. The conductive bump may be a micro-bump, a metal pillar, an electroless nickel-electroless palladium-immersion gold (ENEPIG) formed bump, a controlled collapse chip connection (C4) bump, a ball grid array (BGA) bump, or the like. The conductive bumps may be solder free and may have substantially vertical sidewalls.

In FIG. 8A, the ETT transmitter 100, the capacitor Cac, and the ETT receiver 200 of the ETT 10 are formed in the interposer 830A. The transfer lane 150 is a conductive trace extending between the conductive terminals 815 and 825. In some embodiments, the length of the transfer lane 150 is greater than 1 mm. In other words, the transfer lane 150 is a single transmission line rather than consisting of re-buffers formed by the segmented transmission lines (e.g., the length of the segmented transmission line is equal to or less than 0.2 mm) and the inverters or buffers, thereby decreasing power consumption caused by the re-buffers and improving eye opening. For example, when the re-buffers are replaced by the ETTs in an interposer, it can reduce power consumption in the interposer by more than half.

FIG. 8B is a circuit schematic illustrating a semiconductor package 800B, in accordance with some embodiments of the present disclosure. The semiconductor package 800B includes the first die 810A, the second die 820A and an interposer 830B. The configuration of the semiconductor package 800B of FIG. 8B is similar to the configuration of the semiconductor package 800A of FIG. 8A. The difference between the semiconductor packages 800A and 800B is that the ETT transmitter 100 is removed in the interposer 830B, thereby decreasing more power consumption. In some embodiments, the ETT transmitter 100 is integrated in the transmitter 812 of the first die 810A.

FIG. 8C is a circuit schematic illustrating a semiconductor package 800C, in accordance with some embodiments of the present disclosure. The semiconductor package 800C includes the first die 810B, the second die 820B and an interposer 830C. The configuration of the semiconductor package 800C of FIG. 8C is similar to the configuration of the semiconductor package 800A of FIG. 8A. The difference between the semiconductor packages 800A and 800C is that the ETT transmitter 100 is integrated in the transmitter 812 of the first die 810B and the ETT receiver 200 is integrated in the receiver 822 of the second die 820B, thereby decreasing more power consumption. Furthermore, the interposer 830C is a passive interposer that is free of active device, thereby decreasing design complexity. In the first die 810B, the ETT transmitter 100 is configured to provide the signal S1 according to the input signal DIN to the interposer 830C through the conductive terminal 815. In the second die 820B, the ETT receive 200 is configured to receive the signal S3 from the conductive terminal 825 to generate the output signal DOUT.

FIG. 8D is a circuit schematic illustrating a semiconductor package 800D, in accordance with some embodiments of the present disclosure. The semiconductor package 800D includes the first die 810C, the second die 820B and an interposer 830D. The configuration of the semiconductor package 800D of FIG. 8D is similar to the configuration of the semiconductor package 800C of FIG. 8C. The difference between the semiconductor packages 800C and 800D is that the capacitor Cac is implemented in the first die 810C in mature process. In the first die 810C, the ETT transmitter 100 is configured to provide the signal S1 to the capacitor Cac, so as to provide the signal S2 to the interposer 830D through the conductive terminal 815. In the second die 820B, the ETT receive 200 is configured to receive the signal S3 from the conductive terminal 825 to generate the output signal DOUT.

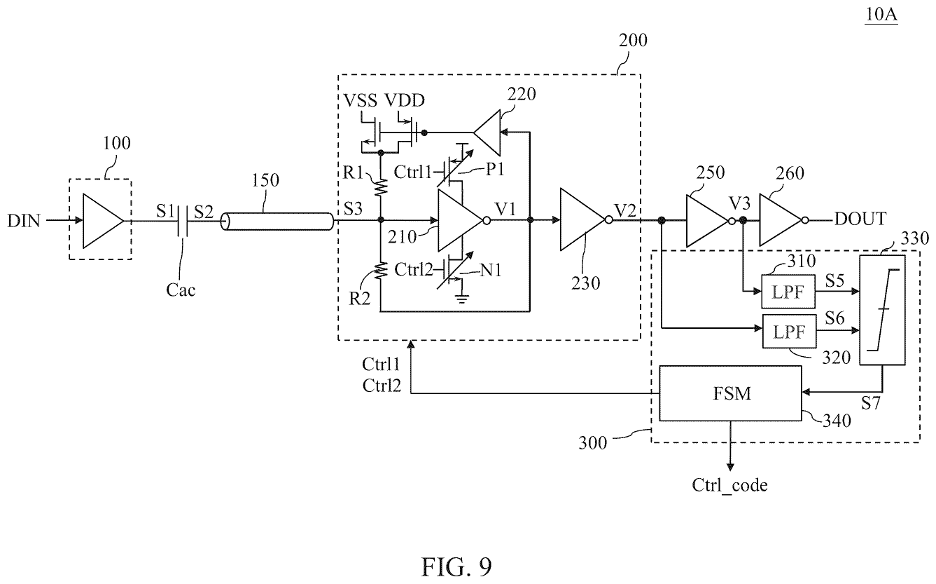

FIG. 9 is a circuit schematic of the ETT 10A, in accordance with some embodiments of the present disclosure. Compared with the ETT 10 of FIG. 1, the ETT 10A of FIG. 9 further includes a calibration circuit 300 and the inverters 250 and 260. The calibration circuit 300 includes the low-pass filters (LPFs) 310 and 320, a slicer 330, and a finite state machine (FSM) 340. The inverters 250 and 260 and the inverter 230 are connected in series. The inverter 250 is configured to receive the signal V2 from the inverter 230 and generate the signal V3 to the inverter 260 and the LPF 310. In some embodiments, the length of the transfer lane 150 in the ETT 10A may be 3000 μm. In some embodiments, the ETT 10 with the calibration circuit 300 is arranged for a clock lane, and the ETT 10 without the calibration circuit 300 is arranged for a signal lane.

In the calibration circuit 300, the LPF 310 is configured to filter the signal V3 (e.g., accumulate the phase difference of the signal V3) to provide the signal S5, and the LPF 320 is configured to filter the signal V2 (e.g., accumulate the phase difference of the signal V2) to provide the signal S6. The slicer 330 is configured to determine the quadrature error according to the signals S5 and S6 to provide the signal S7 to the FSM 340. The FSM is configured to provide the control signals Ctrl1 and Ctrl2 to the ETT receiver 200 according to the signal S7. In response to the control signals Ctrl1 and Ctrl2, the sizes or bias voltages of the P-type transistor P1 and the N-type transistor N1 are adjusted, so as to control the rise and fall transitions of the signal V1, thus the UI of the signal V1 is adjusted and the eye opening of signal V1 is increased. Therefore, the UI and the eye opening of output signal DOUT are increased, accordingly. In some embodiments, the resistors R1 and R² are variable, and the FSM 340 is configured to further provide additional control signals to adjust the resistance values of resistors R1 and R2, so as to control the signal S3. Furthermore, the FSM 340 is configured to further provide the control code Ctrl_code corresponding to the control signals Ctrl1 and Ctrl2 to other ETTs 10 in the same package. Furthermore, the calibration circuit 300 and the logic circuit of control code Ctrl_code are disposed on the same die or interposer as the ETT receiver 200. By using the calibration circuit 300, a duty cycle of a clock signal transmitted in a clock lane is detected and calibrated for PVT (i.e., process, voltage, temperature) variation.

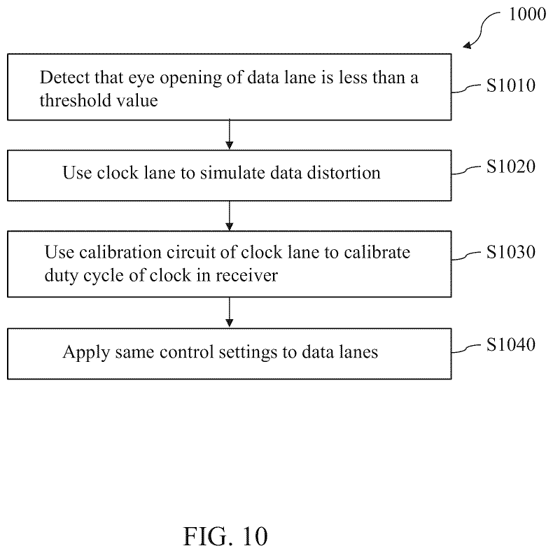

FIG. 10 illustrates a calibration method 1000, in accordance with some embodiments of the present disclosure. First, in operation S1010, it is detected that eye opening of a signal in data lane is less than a threshold value. In some embodiments, the eye opening is decreased because of the high voltage level VH and the low voltage level VL are impacted by the variation of the internal resistance of the inverter 210 caused by process corners. In operation S1020, a clock lane with the ETT 10A is used to simulate or obtain the distortion in the data lane. As described above, a clock signal is used as the input signal DIN to the ETT transmitter 100 of the ETT 10A, and the output signal DOUT is received for analysis. In operation S1030, the calibration circuit 300 of the ETT 10A is used to calibrate the clock signal in the ETT receiver 200 with the control signals Ctrl1 and Ctrl2, to control the duty cycle of the signal S2 to reach a specific value, e.g., 50%. In operation S1040, the control settings (e.g., the control code Ctrl_code corresponding to the control signals Ctrl1 and Ctrl2) of calibration circuit 300 of the ETT 10A is applied to the data lanes, so as to control the P-type transistor P1 and N-type transistor N1 in the ETT 10 of each data lane, thereby maximizing the eye openings at the data lanes.

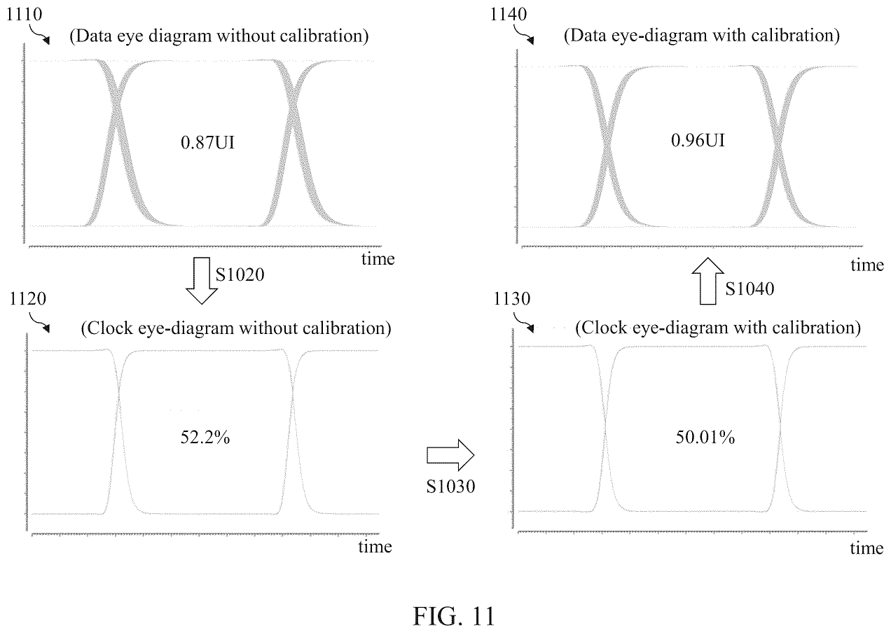

FIG. 11 illustrates various phases in the calibration method 1000 of FIG. 10, in accordance with some embodiments of the present disclosure. In phase 1110, the signal in the data lane is analyzed (or detected) to obtain that the UI (e.g., 0.87 UI) of signal in eye diagram is less than a threshold value (e.g., 0.9 or 0.95 UI). In phase 1120, the clock signal in the clock lane is analyzed to obtain the duty cycle of clock signal in eye diagram after the operation S1020 of FIG. 10 is performed. In phase 1130, the duty cycle of clock signal is adjusted after the operation S1030 of FIG. 10 is performed. In phase 1140, the UI (e.g., 0.96 UI) of signal in eye diagram is increased after the operation S1040 of FIG. 10 is performed. In a worst case that including deterministic jitter (DJ) in the signal S1 and channel cross-talk effect in the signal S3 with the transfer lane 150 having 1600 μm length, the output signal DOUT still has sufficient eye opening.

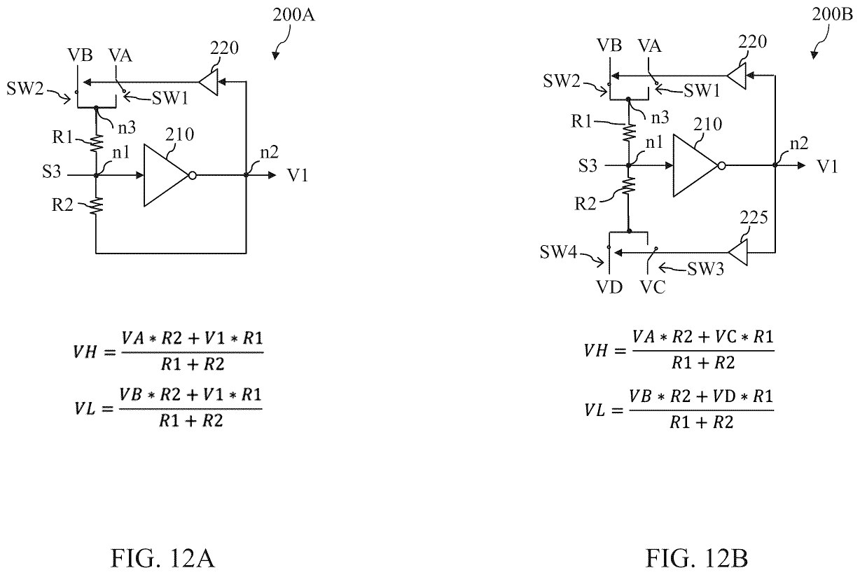

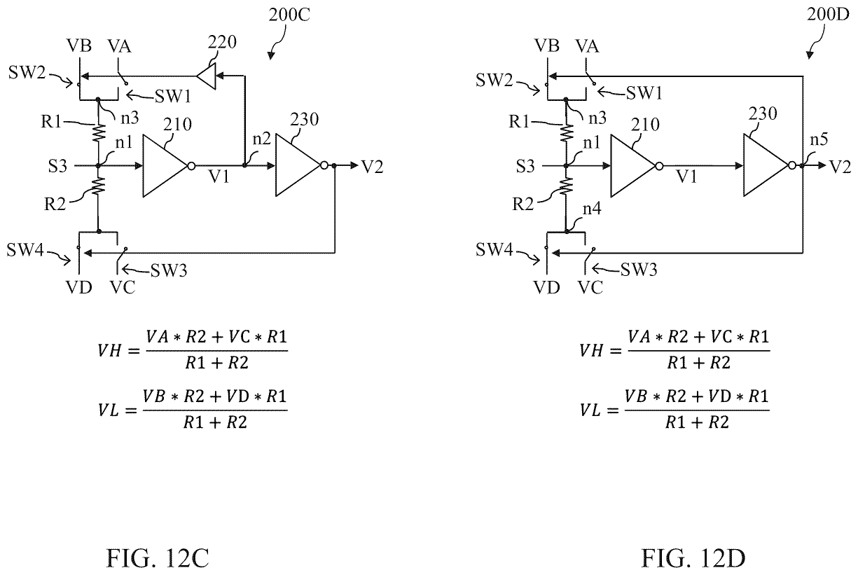

FIG. 12A is a circuit schematic of an ETT receiver 200A, in accordance with some embodiments of the present disclosure. The configuration of the ETT receiver 200A of FIG. 12A is similar to the configuration of the ETT receiver 200 of FIG. 1. The difference between the ETT receivers 200A and 200 is that the P-type transistor P2 and the N-type transistor N2 in the ETT receivers 200 are replaced with the switches SW1 and SW2 in the ETT receivers 200A, respectively. The switch SW1 is coupled between the node n3 and a node of a reference voltage VA, and the switch SW2 is coupled between the node n3 and a node of a reference voltage VB. The switches SW1 and SW2 are controlled by the output of the buffer 220. Each of the reference voltages VA and VB is provide by a low-dropout regulator (LDO), and the reference voltage VA is greater than the reference voltage VB, i.e., VA>VB. To simplify the explanation, the P-type transistor P1 controlled by the control signal Ctrl1 and the N-type transistor N1 controlled by the control signal Ctrl2 are omitted. In some embodiments, the ETT receivers 200A of all lanes in the same interposer share the same LDO for the reference voltage VA and the same LDO for the reference voltage VB. In some embodiments, the reference voltages VA and VB are equal to the power supply voltages VDD and VSS, respectively. In some embodiments, the reference voltage VA is less than the power supply voltages VDD. In some embodiments, the reference voltage VB is greater than the power supply voltages VSS. The high voltage level VH of the signal S3 is determined according to the resistors R1 and R2, the reference voltage VA and the signal V1 at the node n2, i.e., the switch SW1 is turned on and the switch SW2 is turned off. The low voltage level VL of the signal S3 is determined according to the resistors R1 and R2, the reference voltage VB and the signal V1 at the node n2, i.e., the switch SW1 is turned off and the switch SW2 is turned on.

FIG. 12B is a circuit schematic of an ETT receiver 200B, in accordance with some embodiments of the present disclosure. The configuration of the ETT receiver 200B of FIG. 12B is similar to the configuration of the ETT receiver 200A of FIG. 12A. The difference between the ETT receivers 200A and 200B is that the ETT receiver 200B further includes the switches SW3 and SW4 and the buffer 225. The buffer 225 is coupled between the node n2 and the control terminals of the switches SW3 and SW4. The switch SW3 is coupled between the resistor R2 and a node of a reference voltage VC, and the switch SW4 is coupled between the resistor R2 and a node of a reference voltage VD. The switches SW3 and SW4 are controlled by the output of the buffer 225. Each of the reference voltages VC and VD is provide by a LDO. In some embodiments, the reference voltage VD is greater than or equal to the reference voltage VC, i.e., VC≤VD. In some embodiments, the ETT receivers 200B of all lanes in the same interposer share the same LDO for the reference voltage VC and the same LDO for the reference voltage VD. The high voltage level VH of the signal S3 is determined according to the resistors R1 and R2, and the reference voltages VA and VC, i.e., the switches SW1 and SW3 are turned on and the switches SW2 and SW4 are turned off. The low voltage level VL of the signal S3 is determined according to the resistors R1 and R2, and the reference voltages VB and VD, i.e., the switches SW1 and SW3 are turned off and the switches SW2 and SW4 are turned on. Therefore, the high voltage level VH and the low voltage level VL are independent of the signal V1.

FIG. 12C is a circuit schematic of an ETT receiver 200C, in accordance with some embodiments of the present disclosure. The configuration of the ETT receiver 200C of FIG. 12C is similar to the configuration of the ETT receiver 200B of FIG. 12B. The difference between the ETT receivers 200B and 200C is that the switches SW3 and SW4 are controlled by the signal V2 from the inverter 230. As described above, the signal V2 has larger voltage swing V_{SW2}, thus the buffer 225 is removed. The high voltage level VH of the signal S3 is determined according to the resistors R1 and R2, and the reference voltages VA and VC, i.e., the switches SW1 and SW3 are turned on and the switches SW2 and SW4 are turned off. The low voltage level VL of the signal S3 is determined according to the resistors R1 and R2, and the reference voltages VB and VD, i.e., the switches SW1 and SW3 are turned off and the switches SW2 and SW4 are turned on. Therefore, the high voltage level VH and the low voltage level VL are independent of the signals V1 and V2.

FIG. 12D is a circuit schematic of an ETT receiver 200D, in accordance with some embodiments of the present disclosure. The configuration of the ETT receiver 200D of FIG. 12D is similar to the configuration of the ETT receiver 200C of FIG. 12C. The difference between the ETT receivers 200C and 200D is that the switches SW1 and SW2 are controlled by the signal V2 from the inverter 230. As described above, the signal V2 has larger voltage swing V_{SW2}, thus the buffer 220 is removed. The high voltage level VH of the signal S3 is determined according to the resistors R1 and R2, and the reference voltages VA and VC, i.e., the switches SW1 and SW3 are turned on and the switches SW2 and SW4 are turned off. The low voltage level VL of the signal S3 is determined according to the resistors R1 and R2, and the reference voltages VB and VD, i.e., the switches SW1 and SW3 are turned off and the switches SW2 and SW4 are turned on. Therefore, the high voltage level VH and the low voltage level VL are independent of the signals V1 and V2.

According to some embodiments, a semiconductor package is provided. The semiconductor package includes an interposer, a first die and a second die over the interposer, and an edge-triggered transceiver configured to receive an input signal and provide an output signal. The edge-triggered transceiver includes a transfer lane disposed in the interposer, a capacitor coupled to a first end of the transfer lane, a transmitter configured to receive the input signal and provide a first signal to the capacitor, and a receiver configured to receive a second signal corresponding to the first signal from the transfer lane and provide the output signal. The receiver includes a first inverter having an input terminal coupled to a second end of the transfer lane and an output terminal, a first resistor coupled to the input terminal of the first inverter, a second resistor coupled between the input terminal and the output terminal of the first inverter, a first switch coupled between the first resistor and a node of a first reference voltage, and a second switch coupled between the first resistor and a node of a second reference voltage that is less than the first reference voltage. The first inverter is configured to receive the second signal and provide a third signal to turn on one of the first switch and the second switch.

According to some embodiments, an edge-triggered transceiver is provided. The edge-triggered transceiver includes a transmission line disposed in an interposer of a semiconductor package, a capacitor coupled to a first end of the transmission line, a transmitter configured to receive an input signal and provide a first signal to the capacitor, and a receiver configured to receive a second signal corresponding to the first signal from the transmission line and provide an output signal. The receiver includes a first inverter having an input terminal coupled to a second end of the transmission line and an output terminal, a first resistor coupled to the input terminal of the first inverter, a first switch coupled between the first resistor and a node of a first reference voltage, a second switch coupled between the first resistor and a node of a second reference voltage that is less than the first reference voltage, a second resistor coupled to the input terminal, a third switch coupled between the second resistor and a node of a third reference voltage, and a fourth switch coupled between the second resistor and a node of a fourth reference voltage that is greater than the third reference voltage. The first inverter is configured to receive the second signal and provide a third signal to turn on one of the first switch and the second switch and one of the third switch and the fourth switch.

According to some embodiments, a calibration method for an edge-triggered transceiver in a semiconductor package is provided. The edge-triggered transceiver includes a transfer lane disposed in an interposer of the semiconductor package. A clock signal is provided to a transmitter of the edge-triggered transceiver, so as to provide a first signal to a capacitor of the edge-triggered transceiver. The transfer lane has a first end coupled to the capacitor and a second end coupled to a receiver of the edge-triggered transceiver. The receiver includes a first inverter having an input terminal coupled to the second end of the transfer lane and an output terminal, a first resistor coupled to the input terminal of the first inverter, a second resistor coupled between the input terminal and the output terminal of the first inverter, a first switch coupled between the first resistor and a node of a first reference voltage, and a second switch coupled between the first resistor and a node of a second reference voltage that is less than the first reference voltage. The first inverter is configured to receive a second signal from the transfer lane and provide a third signal to turn on one of the first switch and the second switch. An output signal corresponding to the third signal is received from the receiver. Transitions of the third signal are adjusted through the first inverter with a control setting, so as to adjust a duty cycle of the output signal to a specific value.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer;
a first die and a second die over the interposer; and
an edge-triggered transceiver configured to receive an input signal and provide an output signal, and comprising:
a transfer lane disposed in the interposer;
a capacitor coupled to a first end of the transfer lane;
a transmitter configured to receive the input signal and provide a first signal to the capacitor; and
a receiver configured to receive a second signal corresponding to the first signal from the transfer lane and provide the output signal, and comprising:
a first inverter having an input terminal coupled to a second end of the transfer lane and an output terminal;
a first resistor coupled to the input terminal of the first inverter;
a second resistor coupled between the input terminal and the output terminal of the first inverter;
a first switch coupled between the first resistor and a node of a first reference voltage; and
a second switch coupled between the first resistor and a node of a second reference voltage that is less than the first reference voltage,
wherein the first inverter is configured to receive the second signal and provide a third signal to turn on one of the first switch and the second switch.

2. The semiconductor package of claim 1, wherein the second signal has a high voltage level when the first switch is turned on by the third signal, and the second signal has a low voltage level when the second switch is turned on by the third signal.

3. The semiconductor package of claim 1, wherein the receiver further comprises:
a second inverter coupled to the output terminal of the first inverter, and configured to receive the third signal and provide the output signal; and
a buffer coupled between the output terminal of the first inverter and control terminals of the first and second switches.

4. The semiconductor package of claim 3, wherein a voltage swing of the third signal is less than a voltage swing of the output signal.

5. The semiconductor package of claim 3, wherein the input signal is a clock signal, and the edge-triggered transceiver further comprises a calibration circuit configured to adjust transitions of the third signal through the first inverter according to the output signal, so as to adjust a duty cycle of the third signal.

6. The semiconductor package of claim 1, wherein the edge-triggered transceiver is disposed in the interposer, wherein the transmitter is configured to receive the input signal from the first die through a first conductive terminal, and the receiver is configured to provide the output signal to the second die through a second conductive terminal.

7. The semiconductor package of claim 1, wherein the receiver and the capacitor are disposed in the interposer, wherein the transmitter is configured to provide the first signal to the capacitor through a first conductive terminal, and the receiver is configured to provide the output signal to the second die through a second conductive terminal.

8. The semiconductor package of claim 1, wherein the capacitor is disposed in the interposer, the transmitter is disposed in the first die, and the receiver is disposed in the second die, wherein the transmitter is configured to provide the first signal to the capacitor through a first conductive terminal, and the receiver is configured to receive the second signal from the interposer through a second conductive terminal.

9. The semiconductor package of claim 1, wherein the capacitor and the transmitter are disposed in the first die, and the receiver is disposed in the second die, wherein the capacitor is configured to provide AC component of the first signal to the interposer through a first conductive terminal, and the receiver is configured to receive the second signal from the interposer through a second conductive terminal.

10. The semiconductor package of claim 1, wherein the first switch is a P-type transistor, and the second switch is an N-type transistor.

11. An edge-triggered transceiver, comprising:
a transmission line disposed in an interposer of a semiconductor package;
a capacitor coupled to a first end of the transmission line;
a transmitter configured to receive an input signal and provide a first signal to the capacitor; and
a receiver configured to receive a second signal corresponding to the first signal from the transmission line and provide an output signal, and comprising:
a first inverter having an input terminal coupled to a second end of the transmission line and an output terminal;
a first resistor coupled to the input terminal of the first inverter;
a first switch coupled between the first resistor and a node of a first reference voltage;
a second switch coupled between the first resistor and a node of a second reference voltage that is less than the first reference voltage;
a second resistor coupled to the input terminal;
a third switch coupled between the second resistor and a node of a third reference voltage; and
a fourth switch coupled between the second resistor and a node of a fourth reference voltage that is greater than the third reference voltage,
wherein the first inverter is configured to receive the second signal and provide a third signal to turn on one of the first switch and the second switch and one of the third switch and the fourth switch.

12. The edge-triggered transceiver of claim 11, wherein the second signal has a high voltage level when the first and third switches are turned on by the third signal, wherein the first reference voltage is greater than the third reference voltage.

13. The edge-triggered transceiver of claim 11, wherein the second signal has a low voltage level when the second and fourth switches are turned on by the third signal, wherein the fourth reference voltage is greater than the second reference voltage.

14. The edge-triggered transceiver of claim 11, wherein the receiver further comprises a second inverter coupled to the output terminal of the first inverter and configured to receive the third signal and provide the output signal to turn on one of the third switch and the fourth switch.

15. The edge-triggered transceiver of claim 14, wherein the second signal has a high voltage level when the first and third switches are turned on by the third signal and the output signal, respectively, wherein the first reference voltage is greater than the third reference voltage.

16. The edge-triggered transceiver of claim 14, wherein the second signal has a low voltage level when the second and fourth switches are turned on by the third signal and the output signal, respectively, wherein the fourth reference voltage is greater than the second reference voltage.

17. The edge-triggered transceiver of claim 11, wherein the input signal is obtained from a first die of the semiconductor package through a first conductive terminal between the first die and the interposer, and the output signal is provided to a second die of the semiconductor package through a second conductive terminal between the second die and the interposer.

18. A calibration method for an edge-triggered transceiver in a semiconductor package, wherein the edge-triggered transceiver comprises a transfer lane disposed in an interposer of the semiconductor package, the calibration method comprising:
providing a clock signal to a transmitter of the edge-triggered transceiver, so as to provide a first signal to a capacitor of the edge-triggered transceiver, wherein the transfer lane has a first end coupled to the capacitor and a second end coupled to a receiver of the edge-triggered transceiver, wherein the receiver comprises:
a first inverter having an input terminal coupled to the second end of the transfer lane and an output terminal;
a first resistor coupled to the input terminal of the first inverter;
a second resistor coupled between the input terminal and the output terminal of the first inverter;
a first switch coupled between the first resistor and a node of a first reference voltage; and
a second switch coupled between the first resistor and a node of a second reference voltage that is less than the first reference voltage,
wherein the first inverter is configured to receive a second signal from the transfer lane and provide a third signal to turn on one of the first switch and the second switch;
receiving an output signal corresponding to the third signal from the receiver; and
adjusting transitions of the third signal through the first inverter with a control setting, so as to adjust a duty cycle of the output signal to a specific value.

19. The calibration method of claim 18, further comprising:
applying the control setting to other edge-triggered transceivers in the semiconductor package, so as to adjust a duty cycle of each output signal of the other edge-triggered transceivers to the specific value.

20. The calibration method of claim 18, wherein the second signal has a high voltage level when the first switch is turned on by the third signal, and the second signal has a low voltage level when the second switch is turned on by the third signal.
